(19) United States
(12) Patent Application Publication
(10) Pub. No.: US 2015/0077128 A1
(43) Pub. Date: Mar. 19, 2015

(54) METHOD FOR SENSING OPEN STATE OF BATTERY OF ELECTRONIC PARKING BRAKE SYSTEM

(71) Applicant: HYUNDAI MOBIS CO., LTD., Seoul (KR)

(72) Inventor: Hyeon Seok JEONG, Yongin (KR)

(21) Appl. No.: 14/332,333

(22) Filed: Jul. 15, 2014

(30) Foreign Application Priority Data
Sep. 16, 2013 (KR) 10-2013-0111135

(51) Int. Cl. G01R 31/36; B60T 17/22

(52) U.S. Cl. CPC G01R 31/362; B60T 17/22
USPC 324/433

(57) ABSTRACT

Disclosed is a method for sensing an open state of a battery of an electronic parking brake system, including: setting a target voltage value of the battery; judging an operation state of an EPB; applying current to a motor so as to prevent an operation state of the EPB from being changed according to the operation state of the EPB; measuring a present voltage value of the battery; comparing the target voltage value of the battery and the present voltage value; and recognizing, when the present voltage value is equal to or smaller than the target voltage value, the opening as an opening error of the battery.

### CROSS-REFERENCE TO RELATED APPLICATIONS

This application claims priority to and the benefit of Korean Patent Application No. 10-2013-0111135 filed in the Korean Intellectual Property Office on Sep. 16, 2013, the entire contents of which are incorporated herein by reference.

### TECHNICAL FIELD

The present invention relates to an electronic parking brake system, and more particularly, to a method for sensing an open state of a battery of an electronic parking brake system that can sense, when a battery used in the electronic parking brake system is opened, the opening.

### BACKGROUND ART

An electronic parking brake (hereinafter, referred to as EPB) device represents a device that can apply and release a parking brake by driver's simply operating a switch unlike the existing lever type parking brake.

The EPB includes a cable puller type EPB that acquires braking force by extending a shoe in a drum in hat (DIH) with tension generated by pulling a parking cable through rotation of a motor and a caliper integrated EPB in which a spindle pushes a pad by advancing a piston by rotation of a motor to bring the pad into contact with a disk, thereby acquiring the braking force.

In the electronic parking brake (EPB) system, an electronic control unit (ECU), the motor, a gear, a parking cable, and a braking force sensor are integrally configured. Herein, the electronic control unit (ECU) relatively receives related information from a hydraulic electronic control unit (HECU), an engine electronic control unit (ECU), a transaction control unit (TCU), and the like through a CAN and determines an intention of the driver and thereafter, drives the motor. In this case, a gear is actuated by driving the motor and the parking cable is pulled by actuating the gear to provide the braking force to a vehicle wheel, and as a result, a vehicle is maintained in a stable state.

FIG. 1 is a diagram illustrating an EPB motor driving circuit in the related art.

Referring to FIG. 1, the EPB motor driving circuit is configured in such a manner that F2, F3, F4, and F5 constitute an H-bridge to rotate the motor forward/reversely and F6 for fail safe is applied to forcibly interrupt the motor driving under an error situation.

Circuit A of FIG. 1 is a battery open state sensing circuit and serves to discharge electric charges charged at C1 when the battery is opened to sense the open state of the battery.

The reason that the battery open state sensing circuit in the related art like the EPB motor driving circuit of FIG. 1 is applied will be described below.

1. In a motor that is in an undriven state, F2, F3, F4, F5, and F6 are all maintained in an Off state for safety.

2. A discharge path of the electric charges charged in the C1 when the battery is opened under the situation is constituted by R2 and R3 and a large value of hundreds kΩ is applied to the R2 and the R3 for reducing dark current, and as a result, a discharge effect is slight. Therefore, an additional discharge path is required for a sensing time within 1 second.

3. The discharge path of the electric charges charged at C1 needs the following restrictions.

1) The EPB motor driving circuit should not be operated when an ECU power is turned off in order to prevent the dark current from being generated.

2) The EPB motor driving circuit should be operated in an operating voltage range (battery voltage in the range of 9 V to 16 V).

3) Protection from high voltage (battery voltage of 18 V or more) is required.

The battery open state sensing circuit which is controllable in an MCU is applied by restrictions shown in Item #3.

However, in the EPB motor driving circuit in the related art, since a discharge time is determined by a capacity value at C1 and a resistance value connected between Q101 and C1, a decrease of the resistance value is required to reduce the discharge time as the capacity value of C1 becomes larger and larger. Accordingly, resistance of a high-voltage specification should be applied or an application number of the resistance should be increased, and as a result, a decrease of a PCB clearance and price increase cannot be avoided.

It is inconvenient since the EPB motor driving circuit should be controlled in the MCU, of which two pins of the MCU should be consumed and software should be designed so as to determine an operation/non-operation of the circuit according to a surrounding condition.

### SUMMARY OF THE INVENTION

The present invention has been made in an effort to provide a method for sensing an open state of a battery of an electronic parking braking system that can sense, when a battery stably used in the electronic parking brake system without an additional sensing circuit is opened, the open state.

An exemplary embodiment of the present invention provides a method for sensing an open state of a battery of an electronic parking brake system, including: setting a target voltage value of the battery; judging an operation state of an EPB; applying current to a motor so as to prevent an operation state of the EPB from being changed according to the operation state of the EPB; measuring a present voltage value of the battery; comparing the target voltage value of the battery and the present voltage value; and recognizing, when the present voltage value is equal to or smaller than the target voltage value, the opening as an opening error of the battery.

In applying the current to the motor so as to prevent the operation state of the EPB from being changed, applying current to the motor in a direction in which the EPB is released when the EPB is released and applying current to the motor in a direction in which the EPB is applied may be alternately performed.

The applying of the current to the motor in the direction in which the EPB is released when the EPB is released and the applying of the current to the motor in the direction in which the EPB is applied may be performed during the same time.

In the measuring of the present voltage value of the battery, the applying of the current to the motor in the direction in which the EPB is released when the EPB is released and the measuring of the present voltage value of the battery and the applying of the current to the motor in the direction in which the EPB is applied may be alternately performed.

The applying of the current to the motor so as to prevent the operation state of the EPB from being changed may include setting a target current value of the motor when the EPB is applied; applying current to the motor in the direction in which the EPB is applied; measuring a present current value of the motor; comparing the present current value of the motor and the target current value; and stopping an operation of the EPB when the present current value is larger than the target current value and standing by until the present current value becomes 0.

In the applying of the current to the motor so as to prevent the operation state of the EPB from being changed, after the standing by until the present current value becomes 0, the applying of the current to the motor in the direction in which the EPB is applied may be performed when the present current value is 0 again.

The target current value of the motor may be set to a value which is smaller than the current value of the motor when the applying of the EPB is completed.

According to exemplary embodiments of the present invention, in a method for sensing an open state of a battery of an electronic parking brake system, when a battery stably used in the electronic parking brake system without an additional sensing circuit, the opening can be sensed.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating an EPB motor driving circuit in the related art.

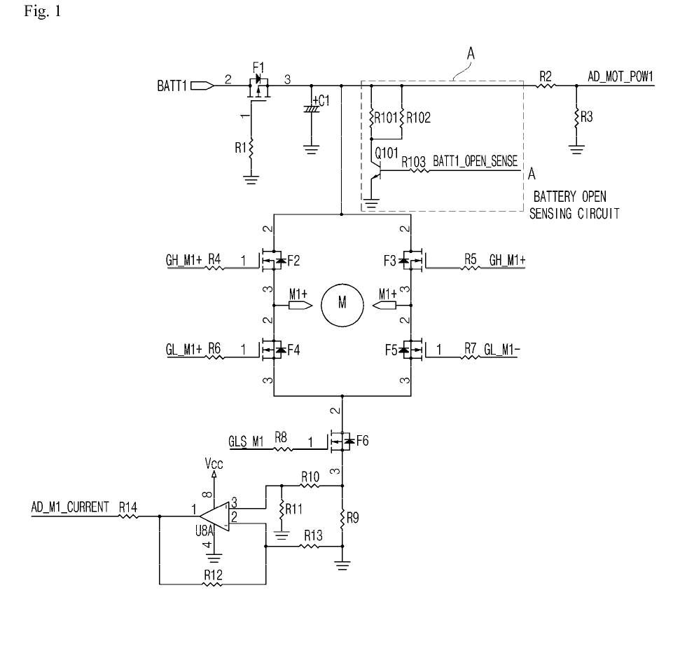

FIG. 2 is a diagram illustrating an EPB motor driving circuit according to an exemplary embodiment of the present invention.

FIG. 3 is a graph illustrating the relationship between an RPM and current of an EPB motor.

FIG. 4 is a graph illustrating characteristics for current of a motor, an RPM of the motor, and parking applying force in each of an EPB applying operation and an EPB releasing operation.

FIGS. 5 and 6 are graphs describing a method of applying current to a motor so that an operating state of an EPB is not changed when the EPB is in a applying state.

FIG. 7 is a flowchart illustrating a method for sensing an open state of a battery of an electronic parking brake system according to another exemplary embodiment of the present invention.

FIG. 8 is a detailed flowchart of FIG. 7.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter, exemplary embodiments of the present invention will be described in detail with reference to the accompanying drawings. When reference numerals refer to components of each drawing, it is to be noted that although the same components are illustrated in different drawings, the same components are referred to by the same reference numerals as possible. Hereinafter, the exemplary embodiment of the present disclosure will be described. However, it should be understood that a technical spirit of the invention is not limited to the specific embodiments, but may be changed or modified by those skilled in the art.

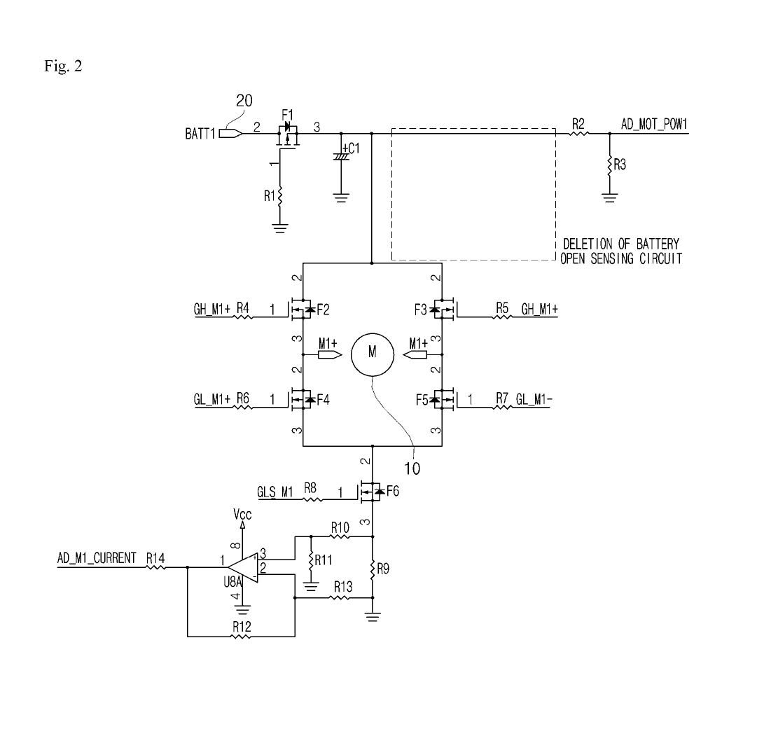

FIG. 2 is a diagram illustrating an EPB motor driving circuit according to an exemplary embodiment of the present invention.

In the exemplary embodiment of the present invention, a circuit for sensing an open state of a battery 20 is deleted from a driving circuit of an EPB motor 10 in the related art and senses, when the battery 20 is opened, the opening by the motor 10 being included in a discharge path of C1.

That is, in the exemplary embodiment of the present invention, an item is denied, that among reasons to which the circuit for sensing the open state of the battery 20 in the related art, F2, F3, F4, F5, and F6 should be all maintained in an Off state for safety in an undriven state of the motor 10.

The reason for turning off a field effect transistor FET in the undriven state of the motor 10 in the related art is that problems described below occur when current flows to the motor 10 through the FET On and when the motor 10 is driven.

First, when the EPB is released by driving the motor 10 while the EPB is in the applying state, a vehicle may move, and as a result, there is a risk that an accident will occur.

Second, if the EPB is additionally applied by driving the motor 10 while the EPB is in the applying state, a stall may occur, and as a result, releasing the EPB may be impossible. If the motor 10 is rotated in an applying direction while applying the parking brake is completed, parking applying force is additionally applied and the motor 10 is intended to be rotated in the applying direction while the parking applying force is no longer applied, further, rotation of the motor 10 is impossible and a stall occurs. When the stall occurs, there is a case in which releasing is impossible.

Third, if the EPB is applied by driving the motor 10 while the EPB is in a releasing state, there is a risk that the accident will occur by unexpected braking while the vehicle is in a driving state.

Fourth, if the EPB is additionally released by driving the motor 10 while the EPB is in the releasing state, a mechanical breakage may be incurred. If the motor 10 is rotated in a releasing direction while the releasing is completed, a releasing interval is additionally ensured. If the motor 10 is intended to be rotated in the releasing direction while a further releasing interval may not be ensured, components of the parking brake hit an inner wall, and as a result, mechanical breakage will occur in a gear or on the inner wall.

In the related art, current is made not to flow in the motor 10 to prevent such a risk. However, the risk occurs because a state of the EPB does change even by excessively driving the motor 10. If the state of the EPB is not changed by preventing the motor 10 from being excessively driven by a predetermined method, a path through which current of the motor 10 flows may be used as the discharge path of the C1.

In this regard, since impedance (approximately tens of mΩ to several Ω) of the motor 10 is much smaller than impedance (approximately hundreds of Ω to tens of kΩ) of the discharge path of the electric charges charged at C1 in the circuit for sensing the open state of the battery 20 in the related art, a time required to sense the open state of the battery 20 is decreased, and as a result, a current mode may be switched to a more rapid fail safe mode.

The motor 10 should be rotated for changing the state of the EPB by driving the motor 10. Accordingly, a method may be considered, which prevents the motor 10 from being rotated or makes the motor 10 be rotated within an allowable level, in order to prevent the state of the EPB from being changed.

In the related art, the method which prevents the motor 10 from being rotated regardless of the state of the EPB is generally applied. In the exemplary embodiment of the present invention, the method is individually applied, which prevents the motor 10 from being rotated or makes the motor 10 be rotated within the allowable level according to the state of the EPB.

The state of the EPB considered in this case may be divided into a applying state and a releasing state.

The applying state means a state in which the EPB applies the parking brake. This state is a state in which the EPB applies the parking applying force so as not to rotate a wheel. The releasing state means a state in which the EPB releases the parking brake. This state is a state in which the EPB releases the parking applying force so as to impose no restriction in rotating the wheel.

Applying and releasing operations of the EPB are determined by a rotation direction of the motor 10.

If a releasing interval is ensured through the releasing operation after general EPB applying in the case of a caliper integral EPB, the mechanical breakage may occur only when the motor 10 is rotated in the releasing direction for a time of tens of seconds. When it is considered that a general releasing operation time is within 1 second, a releasing interval which may be additionally ensured is sufficiently spare.

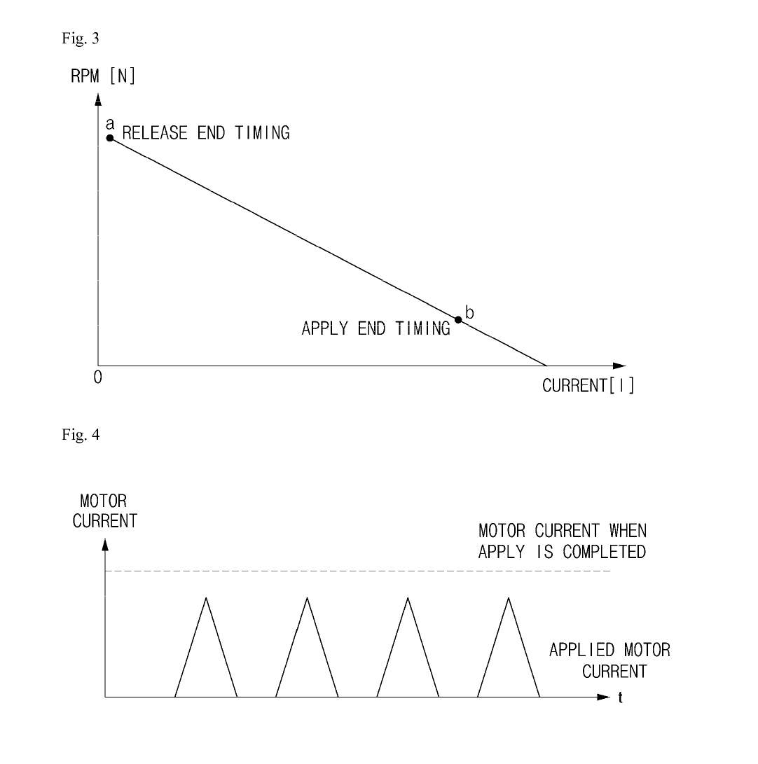

Current required to rotate the motor 10 in the applying direction while the applying of the parking brake is completed needs to have a value higher than current at the time of applying completion. Current at a releasing end timing is required to rotate the motor 10 in the releasing direction at the time of ending the release. The currents are in inverse proportion to each other by an N-I (RPM-current) characteristic of the motor 10. FIG. 3, which is a graph illustrating the relationship between the RPM and the current of the EPB motor 10 illustrates such a characteristic of the motor 10.

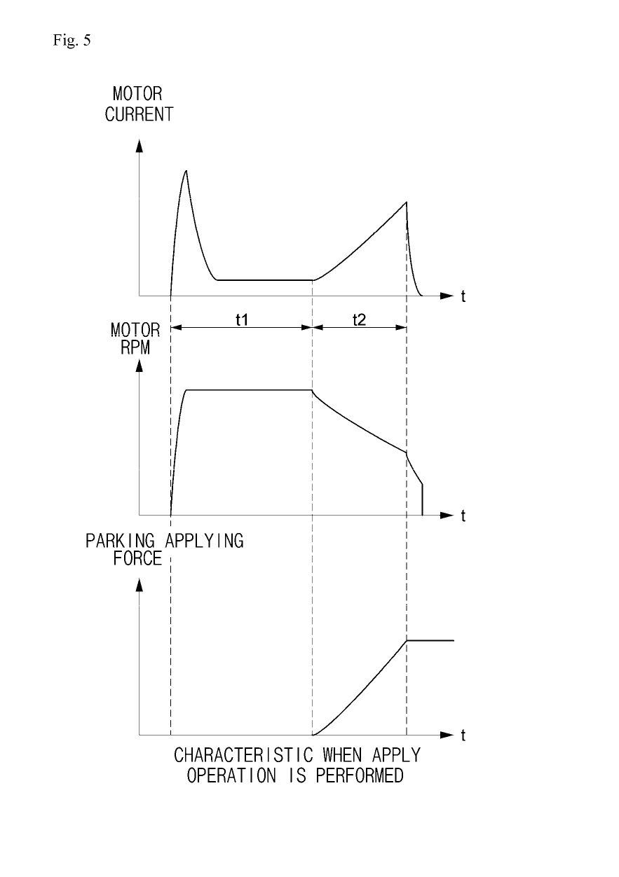

Characteristics regarding the current of the motor 10, the RPM of the motor 10, and the parking applying force when the EPB is applied and released will be illustrated in FIG. 4. In FIG. 4, t1 represents a releasing interval removing interval, t2 represents a parking applying force generation interval, t3 represents a parking applying force releasing interval, and t4 represents a releasing interval ensuring interval.

In the exemplary embodiment of the present invention, since the path through which the current of the motor 10 flows is used as the discharge path of the electric charges charged at C1, a current path is formed so that the motor 10 may be rotated in the applying direction or releasing direction while the applying/releasing of the EPB is completed. An example which may be considered in this case includes four examples shown in Table 1.

TABLE 1

| | | | Current path |
|---|---|---|---|
| No | Items | Initial state | formation direction |
| 1 | Example #1 | Released | Applied |
| 2 | Example #2 | Released | Released |
| 3 | Example #3 | Applied | Applied |
| 4 | Example #4 | Applied | Released |

In considering the characteristics for the current of the motor 10, the RPM of the motor 10, and the parking applying force when the EPB is applied and released, the parking applying force is decreased while the current path is formed in the case of Example #4. Therefore, in the case of Example #4, it is impossible for current to be applied

A case in which an initial state is a releasing state will be first described.

In the case of Example #1, the releasing interval is removed as a check for sensing the open state of the battery 20 is repeated and the parking applying force is generated when the number of checking times reaches a predetermined number of times. In the case of Example #2, the releasing interval is increased as the check for sensing the open state of the battery 20 is repeated, and as a result, a side effect may be caused, which occurs at the time of rotating the motor 10 in the releasing direction while the releasing is completed.

Both Examples #1 and #2 have a common point that Examples #1 and #2 have a problem which occurs when the number of checking times of sensing open state of the battery 20 is increased. Therefore, when Examples #1 and #2 are alternately repeated once, both the problem of Example #1 and the problem of Example #2 may be removed.

First, Example #2 is applied to additionally ensure the releasing interval. Next, Example #1 is performed to remove the releasing interval. In this case, when Examples #1 and #2 are performed during the same time, the additionally ensured releasing interval and the removed releasing interval are the same as each other, and as a result, an initial releasing interval is maintained. When this operation is repeated at one cycle, the problem when only Example #1 or #2 is performed is removed.

When the initial state is the applying state, the current path cannot but formed in the applying direction like Example #3. In this case, a method for avoiding the occurrence of the stall is required. This may be implemented by making the current of the motor 10 flow enough not to generate the additional parking applying force.

The EPB system has a current sensing circuit for measuring the current of the motor 10. The current path may be formed in the applying direction only when an output value of the circuit is lower than the current value of the motor 10 when the applying is completed by using the output value of the circuit.

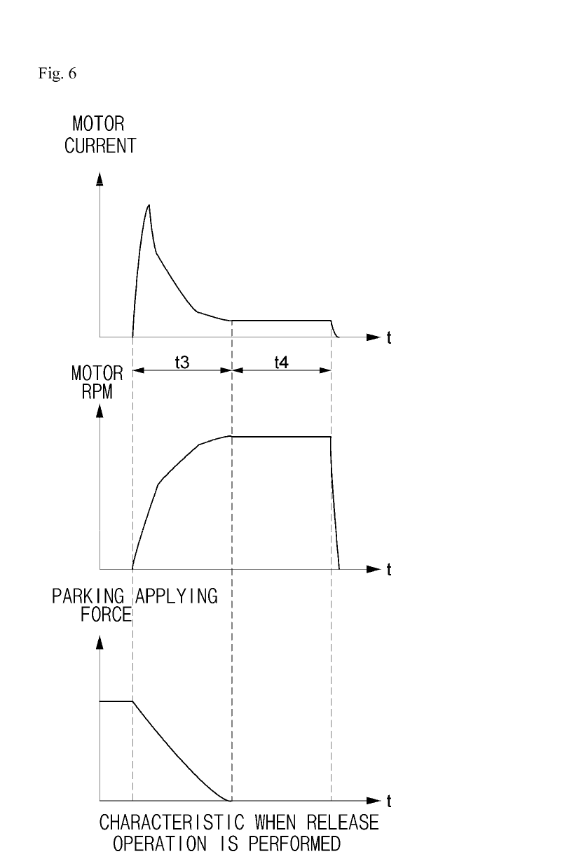

FIGS. 5 and 6 are graphs describing a method of applying current to the motor 10 so that an operating state of an EPB is not changed when the EPB is in a applying state.

If the current value when the applying is completed is 5 A, the current path is formed in the applying direction until the current of motor 10 is 4 A and when the current of the motor 10 is 4 A or more, the current of the motor 10 is made to be 0 by cutting off the current path. Next, the current path is formed in the applying direction until the current of motor 10 is 4 A again and when the current of the motor 10 is 4 A or more, the current of the motor 10 is made to be 0 by cutting off the current path. A value which is smaller than the current value of the motor 10 when the applying is completed is set as a target current value as illustrated in FIGS. 5 and 6 and it is possible to sense the open state of the battery 20 without changing the parking applying force by repeating a method of standing by until the current of the motor 10 becomes 0 by cutting the current path when the target current value is reached.

Hereinafter, the method for sensing the open state of the battery 20 of the electronic parking brake system according to the exemplary embodiment of the present invention will be described based on the aforementioned description.

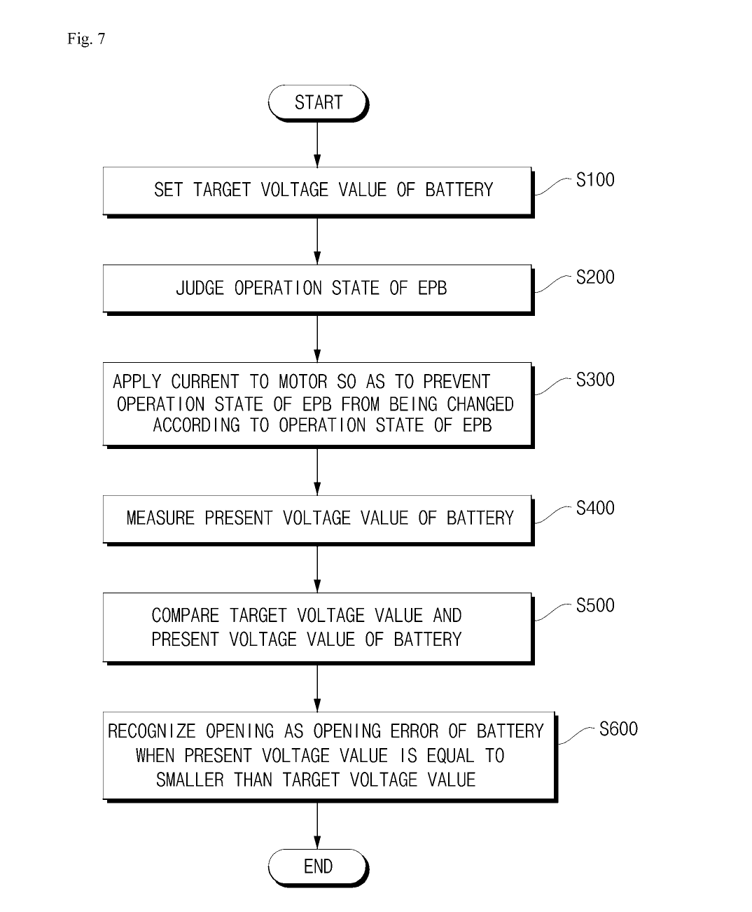

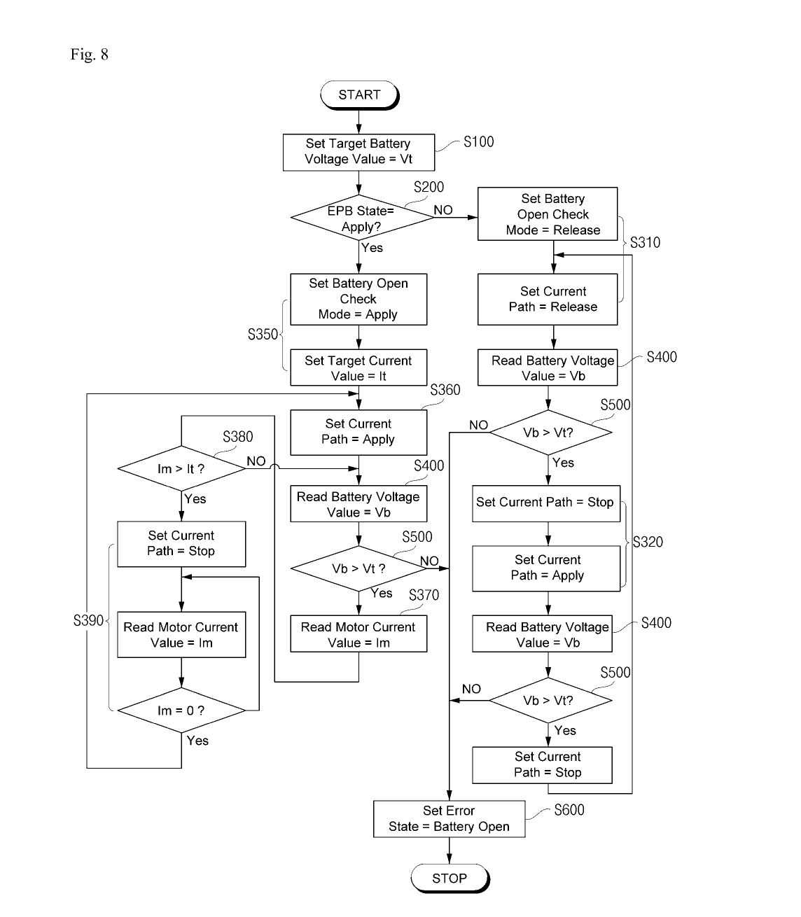

FIG. 7 is a flowchart illustrating a method for sensing an open state of a battery 20 of an electronic parking brake system according to another exemplary embodiment of the present invention. FIG. 8 is a detailed flowchart of FIG. 7.

Referring to FIG. 7, the method for sensing the open state of the battery 20 of the electronic parking brake system according to the exemplary embodiment of the present invention includes setting a target voltage value Vt of the battery 20 (S100), judging an operation state of an EPB (S200), applying current to a motor 10 so to prevent an operation state of the EPB from being changed according to an operation state of the EPB (S300), measuring a present voltage value Vb of the battery 20 (S400), comparing the target voltage value Vt of the battery 20 and the present voltage value Vb (S500), and recognizing, when the present voltage value Vb is equal to or smaller than the target voltage value Vt, the opening as an opening error of the battery 20 (S600).

In the setting of the target voltage value Vt of the battery 20 (S100), the target voltage value Vt is set as a value which is smaller than a voltage value when the battery 20 is normally output.

In the judging of the operation state of the EPB (S200), it is judged whether the EPB is applied or released.

In the applying of the current to the motor 10 so as to prevent the operation state of the EPB from being changed according to the operation state of the EPB (S300), the method is individually applied, which prevents the motor 10 from being rotated according to the EPB state or makes the motor 10 be rotated according to the EPB state.

Referring to FIG. 8, the applying of the current to the motor 10 so as to prevent the operation state of the EPB from being changed (S300) is dividedly performed in the case in which the EPB is applied and in the case in which the EPB is released.

First, when the EPB is released, applying the current to the motor 10 in a direction in which the EPB is released (S310) and applying the current to the motor 10 in a direction in which the EPB is applied (S320) are alternately performed. The applying of the current to the motor 10 in the direction in which the EPB is released (S310) and the applying of the current to the motor 10 in the direction in which the EPB is applied (S320) are performed during the same time. Therefore, the additionally ensured releasing interval and the removed releasing interval are the same as each other in the parking brake as described above, and as a result, the initial releasing interval may be maintained.

After the applying of the current to the motor 10 in the direction in which the EPB is released (S310) and the applying of the current to the motor 10 in the direction in which the EPB is applied (S320), the measuring of the present voltage value Vb of the battery 200 (S400) and the comparing of the target voltage value Vt and the present voltage value Vb of the battery 20 are performed. In this case, when the present voltage value Vb is equal to or smaller than the target voltage value Vt, the opening is recognized as the opening error of the battery 20 (S600) and in the case in which the present voltage value Vb is larger than the target voltage value Vt, each step is repeatedly performed.

When the EPB is applied, setting a target current value It of the motor 10 (S350), applying the current to the motor 10 in the direction in which the EPB is applied (S360), measuring a present current value Im of the motor 10 (S370), comparing the present current value Im of the motor 10 and the target current value It (S380), and standing by until an operation of the EPB is stopped and the present current value Im becomes 0 when the present current value Im is larger than the target current value It (S390) are performed in order to apply current to the motor 10 so that the operation state of the EPB is not changed (S300).

The target current value It of the motor 10 is set to as a value which is smaller than the current value of the motor 10 when applying the EPB is completed. Therefore, a stall phenomenon caused by the generation of excessive applying force may be prevented.

When the present current value Im of the motor 10 is 0, the process is repeated by returning to the applying of the current to the motor 10 in the direction in which the EPB is applied.

In this case, after applying the current to the motor 10, the measuring of the present voltage value Vb of the battery 20 (S400) and the comparing of the target voltage value Vt and the present voltage value Vb of the battery 20 are performed. In this case, when the present voltage value Vb is equal to or smaller than the target voltage value Vt, the opening is recognized as the opening error of the battery 20 (S600) and in the case in which the present voltage value Vb is larger than the target voltage value Vt, each step is continuously repeatedly performed.

When the open state of the battery 20 is not sensed, an unlimited loop is formed and when the unlimited loop is released, another process should be performed due to the occurrence of an interrupt. This includes two cases that include a case in which the EPB applying/releasing operation is required and a case in which the present mode is switched to the fail safe mode due to occurrence of an error other than the opening of the battery 20.

As described above, according to the method for sensing the open state of the battery 20 of the electronic parking brake system according to the exemplary embodiment of the present invention, when the battery 20 stably used in the electronic parking brake system without the additional sensing circuit is opened, the opening may be sensed.

The circuit for sensing the open state of the battery 20 is deleted and applied, and as a result, a spare space of a PCB may be increased and cost may be saved.

As described above, the exemplary embodiments have been described and illustrated in the drawings and the specification. The exemplary embodiments were chosen and described in order to explain certain principles of the invention and their practical application, to thereby enable others skilled in the art to make and utilize various exemplary embodiments of the present invention, as well as various alternatives and modifications thereof. As is evident from the foregoing description, certain aspects of the present invention are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow.

What is claimed is:

1. A method for sensing an open state of a battery of an electronic parking brake system, comprising:
setting a target voltage value of the battery;
judging an operation state of an EPB;
applying current to a motor so as to prevent an operation state of the EPB from being changed according to the operation state of the EPB;
measuring a present voltage value of the battery;
comparing the target voltage value of the battery and the present voltage value; and
recognizing, when the present voltage value is equal to or smaller than the target voltage value, the opening as an opening error of the battery.

2. The method of claim 1, wherein in the applying of the current to the motor so as to prevent the operation state of the EPB from being changed, applying current to the motor in a direction in which the EPB is released when the EPB is released and applying current to the motor in a direction in which the EPB is applied are alternately performed.

3. The method of claim 2, wherein the applying of the current to the motor in the direction in which the EPB is released when the EPB is released and the applying of the current to the motor in the direction in which the EPB is applied are performed during the same time.

4. The method of claim 2, wherein in the measuring of the present voltage value of the battery, the applying of the current to the motor in the direction in which the EPB is released when the EPB is released and the measuring of the present voltage value of the battery and the applying of the current to the motor in the direction in which the EPB is applied are alternately performed.

5. The method of claim 1, wherein the applying of the current to the motor so as to prevent the operation state of the EPB from being changed includes:
setting a target current value of the motor when the EPB is applied;
applying current to the motor in the direction in which the EPB is applied;
measuring a present current value of the motor;
comparing the present current value of the motor and the target current value; and
stopping an operation of the EPB when the present current value is larger than the target current value and standing by until the present current value becomes 0.

6. The method of claim 5, wherein in the applying of the current to the motor so as to prevent the operation state of the EPB from being changed, after the standing by until the present current value becomes 0, the applying of the current to the motor in the direction in which the EPB is applied is performed again when the present current value is 0.

7. The method of claim 5, wherein the target current value of the motor is set to a value which is smaller than the current value of the motor when the applying of the EPB is completed.
